(19) United States
(12) Patent Application Publication
(10) Pub. No.: US 2002/0008082 A1
(43) Pub. Date: Jan. 24, 2002

(54) Local etching apparatus and local etching method

(75) Inventors: Chikai Tanaka, Ayase-Shi (JP); Michihiko Yanagisawa, Ayase-Shi (JP); Shinya Iida, Ayase-Shi (JP); Yasuhiro Horiike, Tokyo (JP)

Correspondence Address: BURR & BROWN, PO BOX 7068, SYRACUSE, NY, 13261-7068, US

(73) Assignee: SpeedFam Co., Ltd.

(21) Appl. No.: 09/898,940

(22) Filed: Jul. 5, 2001

Related U.S. Application Data
(62) Division of application No. 09/347,156, filed on Jul. 2, 1999.

(30) Foreign Application Priority Data
Oct. 13, 1998 (JP) 10-290989

(51) Int. Cl. H01L 21/3065

(52) U.S. Cl. 216/67; 156/345; 438/710

(57) ABSTRACT

A local etching apparatus, and a local etching method are provided to give a high etching rate and enable fine etching. A quartz discharge tube 2 passes through a chamber 9 and has a spray port 21 of a nozzle portion 20 facing a silicon wafer W. A plasma generator 1 causes plasma discharge of a gas fed to the quartz discharge tube 2 so as to produce radicals. An exhaust portion 6 has an exhaust pipe 60 arranged near the nozzle portion 20 so that the spray port 21 of the nozzle portion 20 projects out to the silicon wafer W side from the suction port 60a. The exhaust portion 6 draws into the suction port 60a of the exhaust pipe 60 the reaction products G produced when locally etching the silicon wafer W by the radicals R and exhausts them to the outside of the chamber 9. Desirably, an etching region limiting portion 7 can be provided to feed into the chamber 9 a gas of a predetermined pressure for suppressing the spread of the radicals R sprayed from the spray port 21 of the nozzle portion 20.

### BACKGROUND OF THE INVENTION

1. Field of the Invention

The present invention relates to a local etching apparatus and a local etching method for spraying radicals produced by plasma discharge from a nozzle to a silicon wafer or other object to be etched to locally etch the object to be etched.

2. Description of the Related Art

In the past, as this type of local etching apparatus, there has been a local etching apparatus which causes plasma discharge of CF₄ or another gas to produce F (fluorine) radicals or other radicals and sprays these radicals from a small diameter nozzle to a relatively thick portion of a silicon wafer or other object to be etched to locally etch the relatively thick portion so as to flatten the entire object to be etched.

In this art, it was necessary to prevent the reaction products between the radicals and object to be etched from contaminating the object to be etched, so an exhaust means was provided for exhausting the reaction products to the outside of the chamber of the local etching apparatus.

As an example of such a local etching apparatus provided with an exhaust means, there is the art disclosed in Japanese Patent Laid-Open No. 9-27482.

This local etching apparatus, as shown in FIG. 8, is constructed to cause plasma discharge of a mixed gas of CF₄ and O₂ by a magnetron 100 and spray the produced F radicals from a nozzle 101 to a relatively thick portion of a silicon wafer W to locally etch the same and provide an exhaust pipe 110 constituting part of the exhaust means at the outside of the nozzle 101 to draw the reaction products into the exhaust pipe 110 and exhaust them through the exhaust pipe 110 to the outside of the chamber 120.

In this local etching apparatus of the related art, however, there were the following problems.

First, the front end 101a of the nozzle 101 and the front end 110a of the exhaust pipe 110 were set at the same plane. Further, the front end 101a of the nozzle 101 was structured to be recessed from the exhaust pipe 110. Therefore, part of the F radicals sprayed from the front end 101a was drawn into the exhaust pipe 110 and consequently the etching rate on the silicon wafer W ended up falling.

Next, since the F radicals were just sprayed from the nozzle 101, the gas of the F radicals spread outward as it proceeded downward resulting in the etching region becoming larger. Further, in the above local etching apparatus of the related art, since there was no control means for suppressing this spread of the F radicals, fine etching became impossible.

### SUMMARY OF THE INVENTION

The present invention was made to solve the above problems and has as its object the provision of a local etching apparatus and local etching method giving a high etching rate and enabling fine etching.

To achieve the above object, according to a first aspect of the present invention, there is provided a local etching apparatus comprising: a discharge tube passing through a chamber and with a spray port of a nozzle portion facing an object to be etched in the chamber; a plasma generating means for causing plasma discharge of a predetermined gas fed to the discharge tube so as to produce radicals; and an exhaust means having an exhaust pipe arranged near the nozzle portion so that the spray port of the nozzle portion projects out to the object to be etched side from a suction port of the exhaust pipe and drawing into the suction port of the exhaust pipe the reaction products produced when locally etching the object to be etched by the radicals and exhausting them to the outside of the chamber.

Due to this configuration, the gas fed to the discharge tube is subjected to plasma discharge by the plasma generating means and radicals are produced. These radicals are sprayed from the spray port of the nozzle portion toward the object to be etched whereby the object to be etched is locally etched. The reaction products produced at the time of local etching are exhausted by the exhaust pipe to the outside of the chamber. At this time, since the spray port of the nozzle portion projects out from the suction port of the exhaust pipe to the object to be etched side, almost none of the radicals sprayed from the spray port are drawn into the exhaust pipe.

As a preferable example of the amount of projection of the nozzle portion from the exhaust pipe, according to an embodiment of the invention, the amount of projection of the spray port of the nozzle portion from the suction port of the exhaust pipe is set to a value in the range from 0.5 mm to 5.0 mm.

According to a second aspect of the present invention, there is provided a local etching apparatus comprising: a discharge tube passing through a chamber and with a spray port of a nozzle portion facing an object to be etched in the chamber; a plasma generating means for causing plasma discharge of a predetermined gas fed to the discharge tube so as to produce radicals; an exhaust means having an exhaust pipe arranged near the nozzle portion and drawing into the suction port of the exhaust pipe the reaction products produced when locally etching the object to be etched by the radicals and exhausting them to the outside of the chamber; and an etching region limiting means for feeding into the chamber a gas of a predetermined pressure for suppressing the dispersion of the radicals sprayed from the spray port of the nozzle portion toward the object to be etched.

Due to this configuration, since the dispersion of the radicals sprayed from the spray port toward the object to be etched is suppressed by the gas of a predetermined pressure fed from the etching region limiting means, the sectional area of the flux of the radicals becomes smaller.

Further, according to an embodiment of the invention, the spray port of the nozzle portion is made to project out from the suction port of the exhaust pipe by exactly a value in the range from 0.5 mm to 5.0 mm.

Further, according to an embodiment of the invention, a distance between the spray port of the nozzle portion and the object to be etched is set to a value in the range from 1 mm to 10 mm.

Further, as a preferable example of the pressure of the gas fed by the etching region limiting means, according to an embodiment of the invention, the pressure of the gas fed around the object to be etched by the etching region limiting means is set to 40 percent to 80 percent of the gas pressure inside the nozzle portion.

The gas fed by the etching region limiting means is for limiting the etching region of the object to be etched, so preferably is a gas of a nature not reacting with the radicals sprayed from the nozzle portion or the object to be etched.

Therefore, according to an embodiment of the invention, the gas fed to the chamber by the etching region limiting means is one of nitrogen gas, argon gas, and the predetermined gas fed to the discharge tube.

The steps executed by the local etching apparatuses in their operation also stand as method inventions.

Therefore, according to a third aspect of the present invention, there is provided a local etching method comprising: a plasma generating step for causing plasma discharge of a predetermined gas fed to a discharge tube passing through a chamber and with a spray port of a nozzle portion facing an object to be etched in the chamber so as to produce radicals; a local etching step for directing the radicals sprayed from the spray port of the nozzle portion to a relatively thick portion of the object to be etched to locally etch that relatively thick portion; and a reaction product exhaust step using an exhaust pipe arranged near the nozzle portion so that the spray port of the nozzle portion projects out to the object to be etched side so as to exhaust the reaction products produced in the local etching step outside of the chamber.

Further, according to an embodiment of the invention, the spray port of the nozzle portion is made to project out from the suction port of the exhaust pipe by exactly a value in the range from 0.5 mm to 5.0 mm for the spraying of the radicals.

Further, according to a fourth aspect of the present invention, there is provided a local etching method comprising: a plasma generating step for causing plasma discharge of a predetermined gas fed to a discharge tube passing through a chamber and with a spray port of a nozzle portion facing an object to be etched in the chamber so as to produce radicals; a local etching step for directing the radicals sprayed from the spray port of the nozzle portion to a relatively thick portion of the object to be etched to locally etch that relatively thick portion; a reaction product exhaust step using an exhaust pipe arranged near the nozzle portion so as to exhaust the reaction products produced in the local etching step outside of the chamber; and an etching region limiting step for feeding into the chamber a gas of a predetermined pressure for suppressing the dispersion of the radicals sprayed from the spray port of the nozzle portion toward the object to be etched.

According to an embodiment of the invention, the spray port of the nozzle portion is made to project out from the suction port of the exhaust pipe by exactly a value in the range from 0.5 mm to 5.0 mm for spraying the radicals. According to an embodiment of the invention, the spray port of the nozzle portion is brought close to the object to be etched up to a distance in the range from 1 mm to 10 mm for spraying the radicals. According to an embodiment of the invention, the pressure of the gas fed around the object to be etched in the etching region limiting step is set to 40 percent to 80 percent of the gas pressure inside the nozzle portion. Further, according to an embodiment of the invention, the gas fed to the chamber in the etching region limiting step is one of nitrogen gas, argon gas, and the predetermined gas fed to the discharge tube.

### BRIEF DESCRIPTION OF THE DRAWINGS

The above and other objects, features, and advantages of the present invention will become more readily apparent from the following detailed description of a presently preferred embodiment of the invention taken in conjunction with the accompanying drawings, in which:

FIG. 1 is a schematic sectional view of a local etching apparatus according to a first embodiment of the present invention;

FIG. 2 is a sectional view of an exhaust mechanism;

FIG. 3 is a sectional view for explaining the dispersion suppressing action of F radicals by an etching region limiting gas feeder;

FIG. 4 is a graph of the relationship between a projecting distance of a nozzle portion and a depth of etching of a silicon wafer;

FIG. 5 is a graph of the relationship between the width of an etching region and the pressure of N₂ gas;

FIG. 6 is a graph of the relationship between the distance between the spray port and wafer and the width of the etching region;

FIG. 7 is a graph of the relationship between the distance between the spray port and wafer and the pressure inside the nozzle; and

FIG. 8 is a sectional view of an example of a local etching apparatus of the related art provided with an exhaust means.

### DESCRIPTION OF THE PREFERRED EMBODIMENTS

A preferred embodiment of the present invention will be explained next with reference to the drawings.

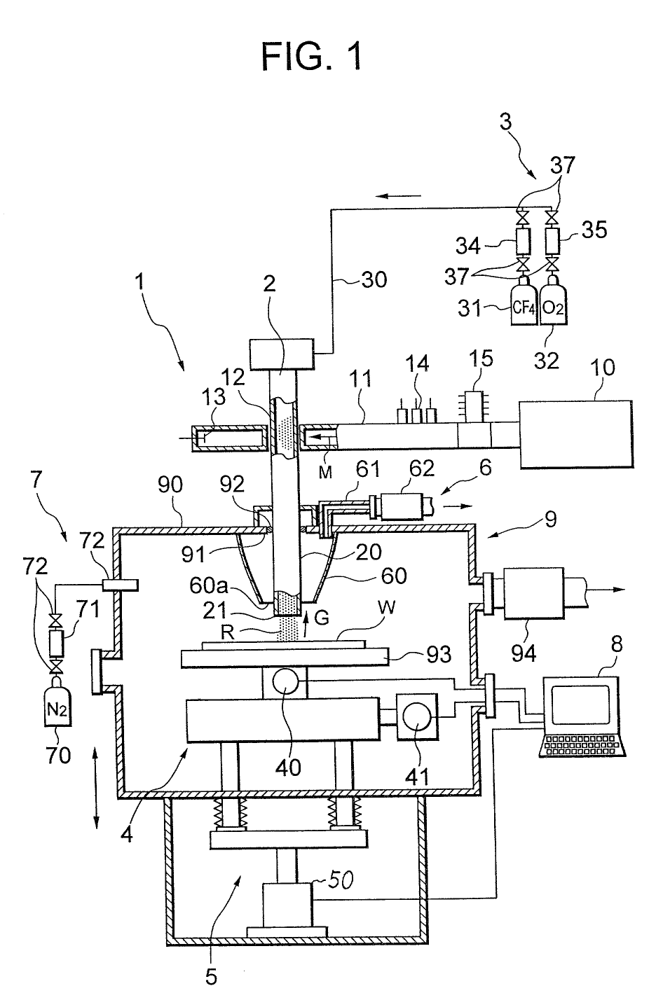

FIG. 1 is a schematic sectional view of a local etching apparatus according to an embodiment of the present invention.

The local etching apparatus is provided with a plasma generator 1 as a plasma generating means, a quartz discharge tube 2, a gas feeder 3, an X-Y drive 4, a Z-drive 5, an exhaust portion 6 as an exhaust means, and an etching region limiting gas feeder 7 as an etching region limiting means.

The plasma generator 1 is a device for causing plasma discharge of gas inside the quartz discharge tube 2 to produce radicals and is comprised of a microwave generator 10 and a waveguide 11.

The microwave generator 10 is a magnetron and can generate a microwave M of a predetermined frequency.

The waveguide 11 is for guiding the microwave M generated by the microwave generator 10 and is fit over the quartz discharge tube 2 through a hole 12.

At the inside of the left end of the waveguide 11 is attached a reflection plate (short plunger) 13 for reflecting the microwave M to form a standing wave. Further, in the middle of the waveguide 11 are attached a 3-stub tuner 14 for positioning the microwave M and an isolator 15 for bending the reflected microwave M heading toward the microwave generator 10 90° in direction (surface direction of FIG. 1).

The quartz discharge tube 2 is a cylinder having a nozzle portion 20 at its lower end, passes through the upper wall 90 of a chamber 9, and has a spray port 21 facing the surface of the silicon wafer W.

Specifically, a hole 91 is made at the center of the upper wall 90 of the chamber 9. The nozzle portion 20 of the quartz discharge tube 2 is inserted into the chamber 9 through this hole 91. An O-ring 92 is fit between the hole 91 and the quartz discharge tube 2 so as to keep the space between the hole 91 and the quartz discharge tube 2 airtight. The outside diameter and inside diameter (diameter of spray port 21) of the quartz discharge tube 2 of this embodiment are set to 13 mm and 9 mm, respectively.

At the upper end of this quartz discharge tube 2 is connected a feed pipe 30 of the gas feeder 3.

The gas feeder 3 is a device for feeding gas into the quartz discharge tube 2 and has a CF₄ (carbon tetrachloride) gas bomb 31 and an O₂ (oxygen) bomb 32. The bombs 31, 32 are connected to the feed pipe 30 through valves 37 and flow controllers 34, 35.

By adopting this configuration for the plasma generator 1, a mixed gas of CF₄ and O₂ is fed from the gas feeder 3 to the quartz discharge tube 2, plasma discharge is caused upon generation of the microwave M from the microwave generator 10, and F (fluorine) radicals R produced by the plasma discharge are sprayed from the spray port 21 of the nozzle portion 20.

The X-Y drive 4 is arranged inside the chamber 9 and supports a chuck 93 from below.

The X-Y drive 4 makes the chuck 93 move in the lateral direction in FIG. 1 by an X-drive motor 40 and makes the chuck 93 and the X-drive motor 40 move in the direction perpendicular to the surface of the paper on which FIG. 1 is drawn by a Y-drive motor 41. That is, it is possible to make the nozzle portion 20 move in the X-Y direction relative to the silicon wafer W by the X-Y drive 4.

The drive operations of the X-drive motor 40 and Y-drive motor 41 of the X-Y drive 4 are controlled by a control computer 8 based on a predetermined program.

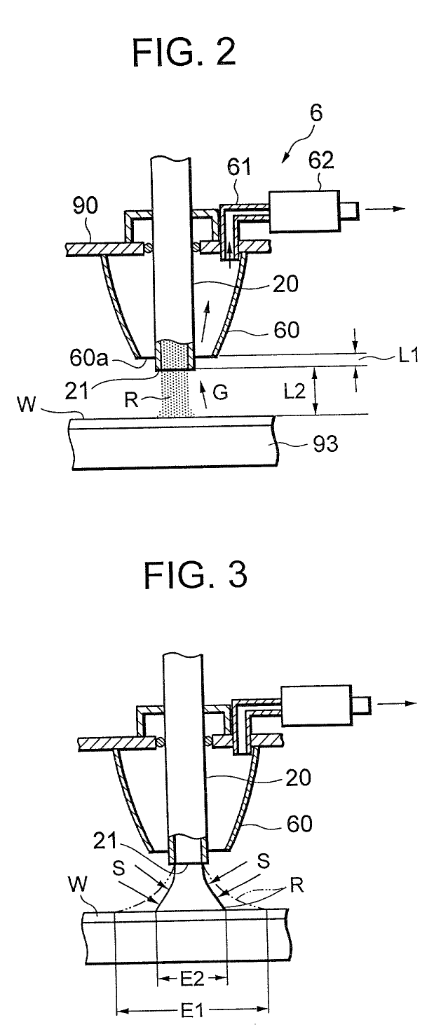

The chamber 9 as a whole is designed to be able to move vertically with respect to the quartz discharge tube 2. The Z-drive 5 supports the chamber 9 from below. The Z-drive 5 makes the chamber 9 as a whole move in the vertical direction by a Z-drive motor 50 and enables the distance between the spray port 21 of the nozzle portion 20 and the surface of the silicon wafer W to be adjusted. In this embodiment, as shown in FIG. 2, the distance L2 between the spray port 21 of the nozzle portion 20 and the silicon wafer W is set to a value in the range of 1 mm to 10 mm.

The exhaust portion 6 is a mechanism for exhausting reaction products G produced at the time of etching the silicon wafer W by the F radicals R to the outside of the chamber 9.

The exhaust portion 6, as shown in FIG. 2, is provided with an exhaust pipe 60, a tube 61, and an exhaust pump 62.

The exhaust pipe 60 is designed to surround the nozzle portion 20 as a whole from the outside and is attached airtightly to the inside surface of the upper wall 90 of the chamber 9. It has at its lower end a suction port 60a with a diameter of 30 mm. The length of the exhaust pipe 60 is set to be shorter than the length of the nozzle portion 20. The front end of the nozzle portion 20 therefore projects out from the suction port 60a of the exhaust pipe 60 to the silicon wafer W side. The amount of projection, that is, the distance L1 between the suction port 60a of the exhaust pipe 60 and the spray port 21 of the nozzle portion 20, is set to a value in the range from 0.5 mm to 5.0 mm.

The tube 61 connects the inside of the exhaust pipe 60 and the exhaust pump 62. Due to this, by actuating the exhaust pump 62, the reaction products G inside the chamber 9 are drawn into the suction port 60a of the exhaust pipe 60. The reaction products G then pass through the tube 61 and can be exhausted to the outside of the chamber 9.

Note that reference numeral 94 in FIG. 1 is a vacuum pump. This vacuum pump 60 may be used to create a state of vacuum inside the chamber 9.

The etching region limiting gas feeder 7 is a device for feeding into the chamber 9 a gas of a predetermined pressure suppressing the dispersion of the F radicals R sprayed from the nozzle portion 20 and is provided with a N₂ (nitrogen) gas S bomb 70, a flow controller 71, and a nozzle 72 attached to the side wall 95 of the chamber 9.

Due to this, by opening the valve 73 of the bomb 70 and controlling the pressure of the N₂ gas S sprayed from the nozzle 72 to the inside of the chamber 9 by the flow controller 71, it is possible to suppress the dispersion of the F radicals R as shown in FIG. 3.

That is, when the chamber 9 is close to a vacuum, as shown by the two-dot chain line, the flux of the F radicals R spreads outward as it proceeds downward and the etching region E1 of the silicon wafer W becomes larger. As opposed to this, when N₂ gas S is fed into the chamber 9, the pressure of the N₂ gas S causes the flux of the F radicals R to be reduced and therefore, as shown by the solid line, the etching region E2 of the silicon wafer W by the F radicals R becomes smaller. Therefore, it becomes possible to control the etching region E2 by the pressure of the N₂ gas S. In this embodiment, the pressure of the N₂ gas S is set to a percentage in the range from 40 percent to 80 percent of the gas pressure inside the nozzle portion 20.

Next, an explanation will be given of the operation of the local etching apparatus of this embodiment. Note that since it is possible to execute the local etching method according to the aspect of the present invention by operating the local etching apparatus, the explanation will be given along with the steps of that method.

First, the plasma generation step is executed.

That is, in FIG. 1, the vacuum pump 94 is driven in the state with the silicon wafer W held by suction against the chuck 93 so as to bring the inside of the chamber 9 to a low air pressure state of 0.1 Torr to 5.0 Torr and the Z-drive 5 is driven to raise the chamber 9 as a whole so as to bring the silicon wafer W to a distance in the range from 1 mm to 10 mm below the nozzle portion 20.

In this state, the valves 37 of the gas feeder 3 are opened, the CF₄ gas and O₂ gas inside the bombs 31, 32 are made to flow into the feed pipe 30, and the mixed gas of the two is fed into the quartz discharge tube 2.

At this time, the opening degrees of the valves 37 are adjusted to maintain the CF₄ gas and O₂ gas at predetermined pressures and the flow controller 34 is used to adjust the flow rate of the CF₄ gas.

In parallel with the feeding of the CF₄ gas, the microwave generator 10 is driven. The microwave M causes plasma discharge of the CF₄ gas present at the discharge position and production of F radicals R. Due to this, the F radicals R are guided into the nozzle portion 20 of the quartz discharge tube 2 and sprayed from the spray port 21 of the nozzle portion 20 to the silicon wafer W side.

Suitably thereafter, the X-Y drive 4 is used to position the silicon wafer W directly under the nozzle portion 20, then the etching region limiting step is executed.

That is, the pressure of the N₂ gas S sprayed from the nozzle 72 to the inside of the chamber 9 is controlled by the flow controller 71 to make the pressure of the N₂ gas S around the silicon wafer W a percentage in the range from 40 percent to 80 percent of the gas pressure inside the nozzle portion 20.

Due to this, the flux of the F radicals R is reduced and, as shown in FIG. 3, the etching region of the silicon wafer W is limited to the small etching region E2.

The local etching step is executed in this state.

That is, the chuck 93 is made to move zigzag in the X-Y direction to make the nozzle portion 20 scan the silicon wafer W in a zigzag pattern. At this time, the relative speed of the nozzle portion 20 with respect to the silicon wafer W is set so as to be substantially inversely proportional to the thickness of the relatively thick portion so the etching time of the relatively thick portion of the silicon wafer W becomes longer and the relatively thick portion is shaved flat. Further, as explained above, since the etching region E2 by the F radicals R is small, it is possible to sequentially etch small relatively thick portions and possible to achieve fine local etching. By etching the entire surface of the silicon wafer W in this way, the local etching step is completed.

A reaction product exhausting step is executed in parallel with the above local etching step.

That is, the exhaust pump 62 of the exhaust portion 6 is operated while executing the above local etching step.

The local etching step, as shown in FIG. 2, causes the production of reaction products G due to the reaction between the F radicals R sprayed from the nozzle portion 20 and the silicon wafer W. The reaction products G would fill the inside of the chamber 9. The reaction products G, however, are drawn into the suction port 60a of the exhaust pipe 60 by the operation of the exhaust pump 62 and are exhausted through the tube 61 to the outside of the chamber 9. The F radicals R sprayed from the nozzle portion 20, however, are also liable to be exhausted by the exhaust portion 6. As explained above, however, the front end of the nozzle portion 20 projects out from- the suction port 60a of the exhaust pipe 60 to the silicon wafer W side by exactly a value in the range from 0.5 mm to 5.0 mm. Further, the F radicals R are sprayed from the nozzle portion 20 at a considerable pressure. Therefore, almost none of the F radicals R sprayed from the nozzle portion 20 are drawn in by the exhaust portion 6. Substantially all of F radicals R contribute to the etching of the silicon wafer W. As a result, the etching rate becomes far greater than the etching rate by the local etching apparatus of the related art explained above.

In this way, according to the local etching apparatus of this embodiment, since the nozzle portion 20 is made to project out from the exhaust pipe 60 to prevent the F radicals R from being drawn in by the exhaust portion 6 and the flux of F radicals R sprayed from the nozzle portion 20 can be reduced to make the etching region smaller, it is possible to improve the etching rate of the silicon wafer W and finely etch the silicon wafer W.

The present inventors conducted the following experiments to provide evidence of this point.

First, a first experiment was conducted to determine the relationship between the amount of projection of the nozzle portion 20 from the exhaust pipe 60, that is, the distance L1 between the spray port 21 of the nozzle portion 20 and the suction port 60a of the exhaust pipe 60, and the etching rate of the silicon wafer W.

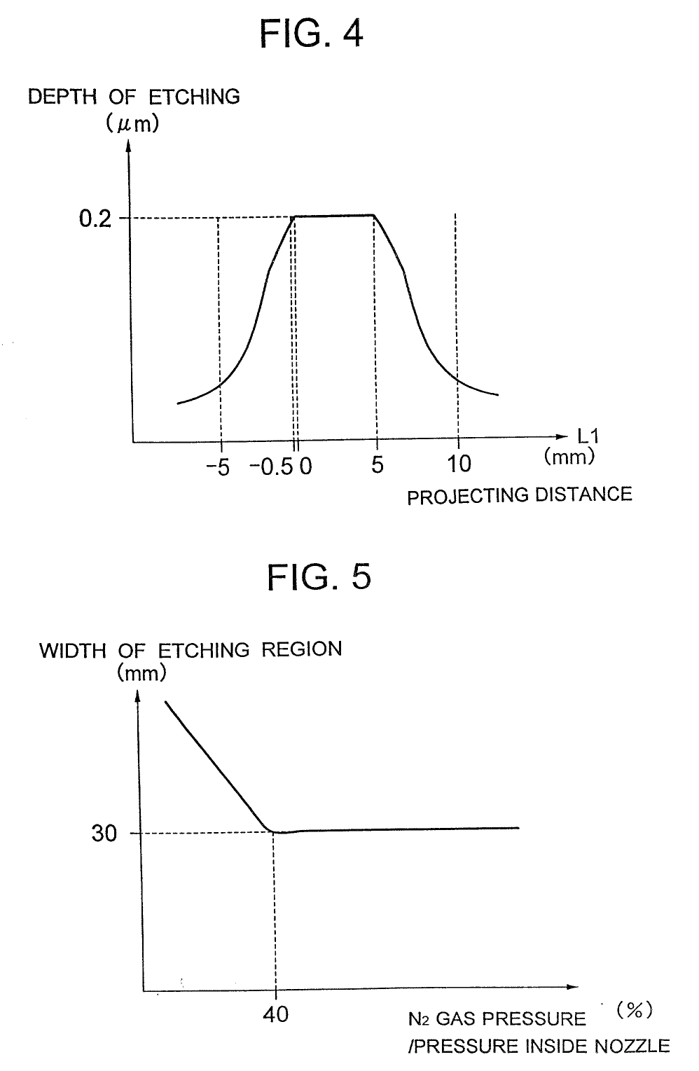

In this experiment, the flow controllers 34, 35 were controlled to make the flow rate of the CF₄ gas and the flow rate of the O₂ gas fed to the quartz discharge tube 2 1000 sccm and 60 sccm, respectively, and the pressure inside the nozzle portion 20 was set to 3.0 Torr. Further, the depth of etching of the silicon wafer W per second was measured while changing the above distance L1. Due to this, the results shown in FIG. 4 was obtained.

FIG. 4 is a graph of the relationship between a projecting distance L1 of the nozzle portion 20 and the depth of etching of the silicon wafer W.

As shown in FIG. 4, when the projecting distance L1 of the nozzle portion 20 is 0 mm or less, that is, when the spray port 21 of the nozzle portion 20 and the suction port 60a of the exhaust pipe 60 are on the same plane or the nozzle portion 20 is pulled back inside the exhaust pipe 60, the depth of etching of the silicon wafer W becomes smaller in proportion to the amount of recess of the nozzle portion 20.

This is considered to be because the more than nozzle portion 20 is recessed in the exhaust pipe 60, the higher the probability of the F radicals R sprayed from the nozzle portion 20 being exhausted by the exhaust portion 6.

As opposed to this, when the projecting distance L1 of the nozzle portion 20 is in the range from 0.5 mm to 5.0 mm, a large depth of etching of 0.2 μm is maintained. This is considered to be because substantially all of the F radicals R sprayed from the nozzle 20 contribute to the etching of the silicon wafer W without being sucked into the exhaust portion 6.

Further, when the projecting distance L1 of the nozzle portion 20 exceeds 5.0 mm, the depth of etching becomes smaller in accordance with this.

From this viewpoint, the inventors reached the conclusion that setting the projecting distance L1 of the nozzle portion 20 to a range from 0.5 mm to 5.0 mm is preferable in improving the etching rate of the silicon wafer W.

Next, the inventors conducted a second experiment to investigate the relationship between the width (diameter) of the etching region by the F radicals R and the pressure of the N₂ gas fed by the etching region limiting gas feeder 7.

In this experiment, the flow controller 71 was controlled under the same conditions as the above first experiment so as to increase the pressure of the N₂ gas S around the silicon wafer W. Due to this, the results shown in FIG. 5 were obtained.

FIG. 5 is a graph of the relationship between the width of the etching region by the F radicals R and the pressure of the N₂ gas S fed by the etching region limiting gas feeder 7.

As shown in FIG. 5, when the pressure of the N₂ gas S was increased up to 40 percent (1.2 Torr) of the pressure inside the nozzle portion 20, the width of the etching region by the F radicals R spreading out downward was reduced to up to 30 mm. When the pressure of the N₂ gas S was increased to 80 percent of the pressure inside the nozzle portion 20, the width of the etching region was maintained at a substantially constant value. When the pressure of the N₂ gas S was increased to over 80 percent of the pressure inside the nozzle portion 20, however, the fall in the etching rate was remarkable. Note that to limit the width of the etching region to 30 mm, the distance L2 between the spray port 21 of the nozzle portion 20 and the surface of the silicon wafer W becomes an issue.

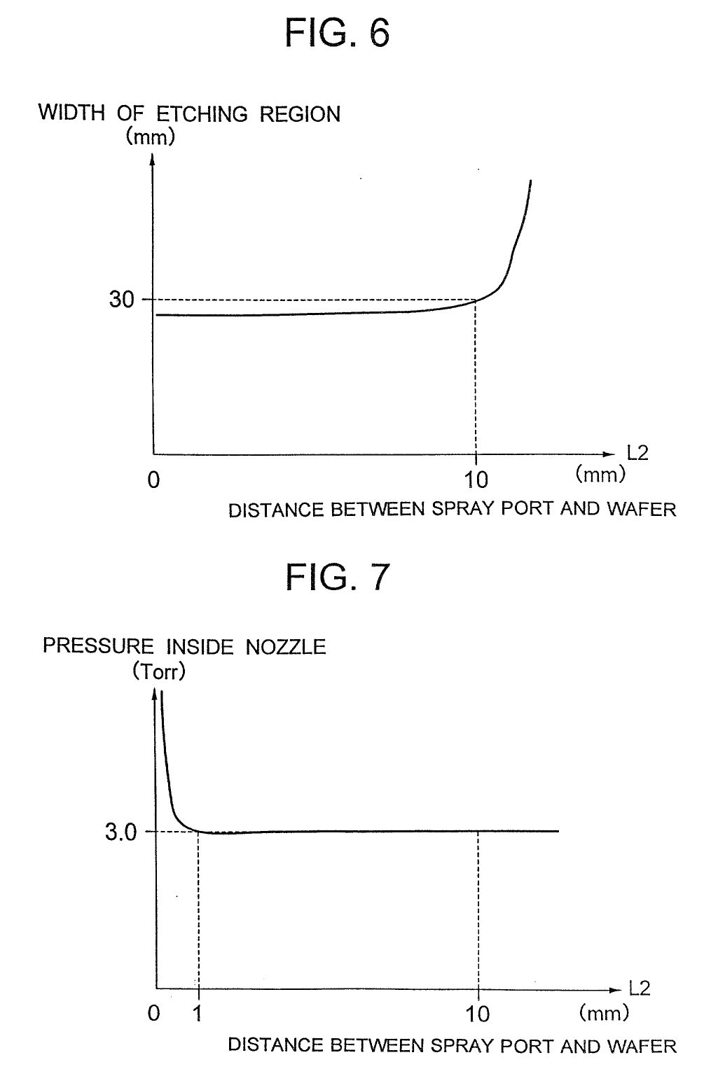

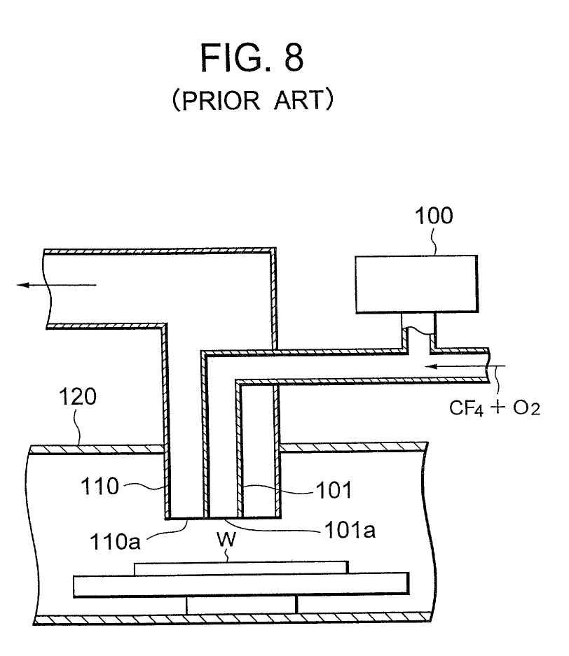

FIG. 6 is a graph of the relationship between the distance L2 between the spray port and wafer and the width of the etching region, while FIG. 7 is a graph of the relationship between the distance L2 between the spray port and wafer and the pressure inside the nozzle portion.

The pressure of the N₂ gas S was set to 40 percent of the pressure inside the nozzle portion 20 and the distance L2 between the spray port and wafer was changed. When the distance L2 between the spray port and wafer was set larger than 10 mm, as shown in FIG. 6, the width of the etching region ended up become larger rapidly. To deal with this, it is necessary to increase the pressure of the N₂ gas S, but if set too large, the N₂ gas S inhibits the F radicals R from reaching the silicon wafer W and the etching rate ends up falling.

On the other hand, when the distance L2 between the spray port and wafer was set smaller than 1 mm, as shown in FIG. 7, the pressure inside the nozzle portion could not be maintained at 3.0 Torr, but rapidly increased and stable etching became impossible. This is considered to have been due to the silicon wafer W itself blocking the F radicals R when the nozzle portion 20 is brought too close to the silicon wafer W and the F radicals R inside the nozzle portion 20 being inhibited from being sprayed from the spray port 21.

From this viewpoint, the inventors reached the conclusion that setting the pressure of the N₂ gas S to 40 percent to 80 percent of the pressure inside the nozzle portion 20 and setting the distance L2 between the spray port and wafer to a range from 1 mm to 10 mm are preferable for stable, fine local etching.

Note that the invention is not limited to the above embodiment. Various modifications and changes may be made within the scope of the gist of the invention.

For example, in the above embodiment, CF₄ and O₂ gas were used as the plasma discharge gas, but CF₄ gas alone is also possible. Further, instead of CF₄ gas, SF₆ (sulfur hexafluoride) gas or NF₃ (nitrogen trifluoride) gas may also be used.

Further, in the above embodiment, N₂ gas S was used as the gas for limiting the etching region, but it is also possible to use Ar gas or the CF₄ gas fed to the quartz discharge tube 2 (SF₆ gas etc. when using SF₆ gas etc.). The point is that any gas not inhibiting the etching of the silicon wafer W may be used as the gas for limiting the etching region.

Further, in the above embodiment, a quartz discharge tube 2 was used as the discharge tube, but an alumina discharge tube may also be used.

Further, in the above embodiment, a plasma generator 1 for generating plasma by generation of microwaves was used as the plasma generating means, but any means able to produce F radicals R may be used. For example, it is of course also possible to use various other types of plasma generators such as plasma generators which produce F radicals R by generation of plasma by high frequency.

As explained in detail above, according to the aspects of the invention, since almost none of the radicals sprayed from the spray port of the nozzle portion are drawn into the suction port of the exhaust pipe, almost all of the radicals sprayed from the spray port contribute to the local etching of the object to be etched and as a result there is the superior effect of improvement of the etching rate.

Further, according to the aspects of the invention, since it is possible to reduce the sectional area of the flux of radicals sprayed from the spray port of the nozzle portion, the etching region of the object to be etched becomes smaller and finer etching of the object to be etched becomes possible to that extent.

What is claimed is:

1. A local etching apparatus comprising:
a discharge tube passing through a chamber and with a spray port of a nozzle portion facing an object to be etched in the chamber;
a plasma generating means for causing plasma discharge of a predetermined gas fed to said discharge tube so as to produce radicals; and
an exhaust means having an exhaust pipe arranged near the nozzle portion so that the spray port of the nozzle portion projects out to the object to be etched side from a suction port of the exhaust pipe and drawing into the suction port of the exhaust pipe the reaction products produced when locally etching the object to be etched by the radicals and exhausting them to the outside of the chamber.

2. A local etching apparatus as set forth in claim 1, wherein the amount of projection of the spray port of the nozzle portion from the suction port of the exhaust pipe is set to a value in the range from 0.5 mm to 5.0 mm.

3. A local etching apparatus comprising:
a discharge tube passing through a chamber and with a spray port of a nozzle portion facing an object to be etched in the chamber;
a plasma generating means for causing plasma discharge of a predetermined gas fed to said discharge tube so as to produce radicals;
an exhaust means having an exhaust pipe arranged near the nozzle portion and drawing into the suction port of the exhaust pipe the reaction products produced when locally etching the object to be etched by the radicals and exhausting them to the outside of the chamber; and
an etching region limiting means for feeding into the chamber a gas of a predetermined pressure for suppressing the dispersion of the radicals sprayed from the spray port of the nozzle portion toward the object to be etched.

4. A local etching apparatus as set forth in claim 3, wherein the spray port of the nozzle portion is made to project out from the suction port of the exhaust pipe by exactly a value in the range from 0.5 mm to 5.0 mm.

5. A local etching apparatus as set forth in claim 3, wherein a distance between the spray port of the nozzle portion and the object to be etched is set to a value in the range from 1 mm to 10 mm.

6. A local etching apparatus as set forth in claim 3, wherein the pressure of the gas fed around the object to be etched by the etching region limiting means is set to 40 percent to 80 percent of the gas pressure inside the nozzle portion.

7. A local etching apparatus as set forth in claim 3, wherein the gas fed to the chamber by the etching region limiting means is one of nitrogen gas, argon gas, and the predetermined gas fed to said discharge tube.

8. A local etching method comprising:
a plasma generating step for causing plasma discharge of a predetermined gas fed to a discharge tube passing through a chamber and with a spray port of a nozzle portion facing an object to be etched in the chamber so as to produce radicals;
a local etching step for directing the radicals sprayed from the spray port of the nozzle portion to a relatively thick portion of the object to be etched to locally etch that relatively thick portion; and
a reaction product exhaust step using an exhaust pipe arranged near the nozzle portion so that the spray port of the nozzle portion projects out to the object to be etched side so as to exhaust the reaction products produced in said local etching step outside of the chamber.

9. A local etching method as set forth in claim 8, wherein the spray port of the nozzle portion is made to project out from the suction port of the exhaust pipe by exactly a value in the range from 0.5 mm to 5.0 mm for the spraying of the radicals.

10. A local etching method comprising:
a plasma generating step for causing plasma discharge of a predetermined gas fed to a discharge tube passing through a chamber and with a spray port of a nozzle portion facing an object to be etched in the chamber so as to produce radicals;
a local etching step for directing the radicals sprayed from the spray port of the nozzle portion to a relatively thick portion of the object to be etched to locally etch that relatively thick portion;
a reaction product exhaust step using an exhaust pipe arranged near the nozzle portion so as to exhaust the reaction products produced in said local etching step outside of the chamber; and
an etching region limiting step for feeding into the chamber a gas of a predetermined pressure for suppressing the dispersion of the radicals sprayed from the spray port of the nozzle portion toward the object to be etched.

11. A local etching method as set forth in claim 10, wherein the spray port of the nozzle portion is made to project out from the suction port of the exhaust pipe by exactly a value in the range from 0.5 mm to 5.0 mm for spraying the radicals.

12. A local etching method as set forth in claim 10, wherein the spray port of the nozzle portion is brought close to the object to be etched up to a distance in the range from 1 mm to 10 mm for spraying the radicals.

13. A local etching method as set forth in claim 10, wherein the pressure of the gas fed around the object to be etched in said etching region limiting step is set to 40 percent to 80 percent of the gas pressure inside the nozzle portion.

14. A local etching apparatus as set forth in claim 10, wherein the gas fed to the chamber in said etching region limiting step is one of nitrogen gas, argon gas, and the predetermined gas fed to the discharge tube.
